(19) United States
(12) Patent Application Publication
(10) Pub. No.: US 2026/0163556 A1
(43) Pub. Date: Jun. 11, 2026

(54) PHASE SHIFT ATTENUATION CIRCUITS, PHASE SHIFT ATTENUATION NETWORK AND RADIO FREQUENCY MICROWAVE SYSTEMS

(71) Applicant: ETRA SEMICONDUCTOR (SUZHOU) CO., LTD., Suzhou (CN)

(72) Inventors: Xinyu LIU, Suzhou (CN); Xiaowei ZHU, Suzhou (CN); Jun CHEN, Suzhou (CN); Jiahui GAO, Suzhou (CN)

(73) Assignee: ETRA SEMICONDUCTOR (SUZHOU) CO., LTD., Suzhou (CN)

(21) Appl. No.: 19/181,318

(22) Filed: Apr. 16, 2025

Related U.S. Application Data
(63) Continuation of application No. PCT/CN2024/138352, filed on Dec. 11, 2024.

(30) Foreign Application Priority Data
Aug. 27, 2024 (CN) 202411184707.2

(51) Int. Cl. H03H 11/16; H01Q 3/30

(52) U.S. Cl. CPC H03H 11/16; H01Q 3/30

(57) ABSTRACT

The present disclosure discloses a phase shift attenuation circuit, a phase shift attenuation network, and a radio frequency (RF) microwave system. The phase shift attenuation circuit comprises a plurality of first differential circuits electrically connected in sequence; an electrical connection between two adjacent first differential circuits of the plurality of first differential circuits including at least one of a straight-through connection or a connection through an attenuator unit; wherein the phase shift attenuation circuit realizes 8-bit step attenuation through the attenuator unit; 7-bit step attenuation among the 8-bit step attenuation is configured to realize a phase shift function, and the 8-bit step attenuation is configured to realize phase shift and attenuation functions. The phase shift attenuation circuit is constructed based on a differential circuit architecture, and is capable of simultaneously realizing the phase shift and attenuation functions by the same circuit.

### CROSS-REFERENCE TO RELATED APPLICATIONS

This application is a Continuation of International Application No. PCT/CN2024/138352, filed on Dec. 11, 2024, which claims priority to Chinese Patent Application No. 202411184707.2, filed on Aug. 27, 2024, the entire contents of each of which are incorporated herein by reference.

### TECHNICAL FIELD

The present disclosure relates to the technical field of wireless communication, and in particular to a high-accuracy and ultra-broadband phase shift attenuation circuit, and a phase shift attenuation network and a radio frequency (RF) microwave system comprising the same.

### BACKGROUND

Modern communication systems (e.g. 5G MIMO communication, LEO satellite communication, etc.) have high requirements for a digital phase shifter and a digital attenuator. The digital attenuator requires low in-band insertion loss and high attenuation accuracy. The digital phase shifter requires low in-band insertion loss, high phase shift accuracy, and small size. The present implementation of the digital phase shifter and the digital attenuator is not compatible with requirements of the modern communication systems for both devices.

Therefore, it is desirable to provide a phase shift attenuation circuit, a phase shift attenuation network, and an RF microwave system that can achieve miniaturization while realizing phase shift and attenuation functions, and has the advantage of high performance.

### SUMMARY

A first aspect of the present disclosure discloses a phase shift attenuation circuit. The phase shift attenuation circuit may comprise: a plurality of first differential circuits electrically connected in sequence; an electrical connection between two adjacent first differential circuits of the plurality of first differential circuits including at least one of a straight-through connection or a connection through an attenuator unit; wherein the phase shift attenuation circuit realizes 8-bit step attenuation through the attenuator unit; 7-bit step attenuation among the 8-bit step attenuation is configured to realize a phase shift function, and the 8-bit step attenuation is configured to realize phase shift and attenuation functions.

In some embodiments of the present disclosure, each of the plurality of first differential circuits may include: one or more first differential input ports, one or more first differential output port, and a plurality of switching tube chips. One of the plurality of switching tube chips may be connected between a positive and negative interface of each of the one or more first differential input ports and a positive and negative interface of each of the one or more first differential output ports. Connection or disconnection between the one or more first differential input ports and the one or more first differential output ports may be achieved by the plurality of switching tube chips to determine the electrical connection between the two adjacent first differential circuits.

In some embodiments of the present disclosure, the plurality of first differential circuits are different.

In some embodiments of the present disclosure, an attenuation range of the 7-bit step attenuation may be in a range of 0-31.75 dB for realizing phase shifting in a range of 0 deg-90 deg; an attenuation range of the 8-bit step attenuation may be in a range of 0-63.75 dB for realizing phase shifting in a range of 0 deg-90 deg and amplitude attenuation.

Another aspect of the present disclosure provides a phase shift attenuation network. The phase shift attenuation network may comprise the phase shift attenuation circuit as described above.

In some embodiments of the present disclosure, the phase shift attenuation network may further comprise: a first node circuit; a second node circuit; and a first signal channel and a second signal channel which are coupled between the first node circuit and the second node circuit. The first node circuit and the second node circuit may include the phase shift attenuation circuit, respectively.

In some embodiments of the present disclosure, the first node circuit and the second node circuit may respectively include a quadrant conversion circuit electrically connected with the phase shift attenuation circuit. The quadrant conversion circuit may be constructed based on a second differential circuit. The second differential circuit may realize quadrant conversion of a phase through connection or disconnection between a positive and negative interface of a second differential input port and a positive and negative interface of a second differential output port, and realize phase shifting in a preset range based on the phase shift attenuation circuit.

In some embodiments of the present disclosure, a phase shift range of the first node circuit or the second node circuit is in a range of 0 deg-360 deg.

In some embodiments of the present disclosure, the second node circuit may include a third differential circuit. The third differential circuit may include: an input differential network including a first port and a second port; an input differential unit including an input differential coupling line; an output differential unit including a first coupling line and a second coupling line; and an output differential network including a first output differential port and a second output differential port. A positive input terminal of the input differential coupling line may be connected with the first port, and a negative input terminal of the input differential coupling line may be connected with the second port. A positive input terminal of the first coupling line may be connected with a positive output terminal of the input differential coupling line, and a negative input terminal of the second coupling line may be connected with a negative output terminal of the input differential coupling line. A negative input terminal of the first coupling line may be connected with a positive input terminal of the second coupling line. A positive interface of the first output differential port may be connected with a positive output terminal of the first coupling line, and a negative interface of the first output differential port may be connected with a negative output terminal of the second coupling line. A positive interface of the second output differential port may be connected with a positive output terminal of the second coupling line, and a negative interface of the second output differential port may be connected with a negative output terminal of the first coupling line. The first output differential port and the second output differential port of the output differential network may be configured to receive a first phase shift signal and a second phase shift signal, respectively. The input differential network may be configured to output a synthesized signal

Another aspect of the present disclosure provides a radio frequency microwave system, comprising the phase shift attenuation circuit or the phase shift attenuation network as described above.

Additional aspects and advantages of the present discourse are given in part in the following description, and in part become apparent from the following description, or are understood through the practice of the present disclosure.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a schematic structural diagram illustrating a phase shift attenuation circuit according to some embodiments of the present disclosure;

FIG. 2 is a schematic structural diagram illustrating a differential circuit according to some embodiments of the present disclosure;

FIG. 3 is a schematic structural diagram illustrating a differential circuit according to some embodiments of the present disclosure;

FIG. 4 is a schematic structural diagram illustrating a phase shift attenuation circuit according to some embodiments of the present disclosure;

FIG. 5 is a schematic structural diagram illustrating a phase shift attenuation network according to some embodiments of the present disclosure;

FIG. 6 is a schematic structural diagram illustrating a first node circuit according to some embodiments of the present disclosure;

FIG. 7 is a schematic structural diagram illustrating a quadrant conversion circuit according to some embodiments of the present disclosure;

FIG. 8(a) is a schematic diagram illustrating an exemplary connection state of a third differential circuit 700 constituting a quadrant conversion circuit according to some embodiments of the present disclosure;

FIG. 8(b) is a schematic diagram illustrating an exemplary connection state of a third differential circuit 700 constituting a quadrant conversion circuit according to some embodiments of the present disclosure;

FIG. 8(c) is a schematic diagram illustrating an exemplary connection state of a third differential circuit 700 constituting a quadrant conversion circuit according to some embodiments of the present disclosure;

FIG. 8(d) is a schematic diagram illustrating an exemplary connection state of a third differential circuit 700 constituting a quadrant conversion circuit according to some embodiments of the present disclosure;

FIG. 9 is a schematic diagram illustrating an exemplary correspondence characteristic between a quadrant and a connection state of a differential circuit according to some embodiments of the present disclosure;

FIG. 10 is a schematic diagram illustrating an exemplary amplitude-phase correspondence according to some embodiments of the present disclosure;

FIG. 11 is a schematic diagram illustrating different exemplary amplitudes according to some embodiments of the present disclosure;

FIG. 12 is a schematic diagram illustrating exemplary S-parameters at different phases under the same amplitude according to some embodiments of the present disclosure;

FIG. 13 is a schematic diagram illustrating exemplary S-parameters at different phases under the same amplitude according to some embodiments of the present disclosure;

FIG. 14 is a schematic diagram illustrating exemplary S-parameters at different phases under the same amplitude according to some embodiments of the present disclosure;

FIG. 15 is a schematic diagram illustrating S-parameters at different phases and phase performance under one attenuation amplitude according to some embodiments of the present disclosure;

FIG. 16 is a schematic diagram illustrating S-parameters at different phases and phase performance under another attenuation amplitude according to some embodiments of the present disclosure;

FIG. 17 is a schematic structural diagram illustrating an exemplary RF/microwave transmitting system according to some embodiments of the present disclosure; and

FIG. 18 is a schematic structural diagram illustrating an exemplary RF/microwave receiving system according to some embodiments of the present disclosure.

### DETAILED DESCRIPTION

In order to make the above purposes, features, and advantages of the present disclosure more apparent and understandable, the following description provides detailed explanations of the specific embodiments of the present disclosure. Many specific details are set forth in the following description to facilitate full understanding of the present disclosure. However, the present disclosure can be implemented in many other ways than those described herein, and those skilled in the art can make similar improvements without violating the connotations of the present disclosure. Therefore, the present disclosure is not limited by the specific embodiments disclosed below.

Unless defined otherwise, all technical and scientific terms used herein have the same meaning as commonly understood by those skilled in the art to which the present disclosure belongs. The terms used herein in the present disclosure are merely for the purpose of describing specific embodiments, not intended to limit the present disclosure. As used herein, the words “including” or “comprising” and similar expressions are intended to indicate that the component or object present before the word covers the component or object listed after the word and its equivalent, and does not exclude other components or objects. As used herein, the term “and/or” includes any and all combinations of one or more related listed items.

The terms “first,” “second,” etc., used in the present disclosure are used to distinguish between similar subjects and are not intended to describe or indicate a particular order or sequence; they should not be construed as indicating or implying relative importance or implicitly specifying the number of technical features indicated. Thus, the features defined as “first” and “second” may expressly or implicitly include one or more of the specified features. In the description of the present disclosure, unless otherwise indicated, “a plurality of” means two or more. In addition, unless otherwise expressly specified and qualified, the terms “connected” and “connecting” should be understood broadly, e.g., as a direct connection, as an indirect connection through an intermediate medium, or a connection within two elements. For those skilled in the art, the specific meanings of the above terms in the present disclosure can be understood according to specific circumstances.

A digital phase shifter and a digital attenuator are widely used in wireless communication. The digital phase shifter modulates the phase of transmitted or received signals, while the digital attenuator modulates their amplitude. Typical applications include 5G MIMO communications and low Earth orbit (LEO) satellite communications. The attenuation range of the digital attenuator directly affects the dynamic range of wireless communication signals, whereas the phase shift range of the digital phase shifter directly affects the phase modulation accuracy of the wireless communication signals.

Current implementations of the digital phase shifter primarily fall into two categories. The first implementation employs a single-ended switch to toggle transmission line phase shift unit network. However, this type of digital phase shifter exhibits significant performance degradation at high frequencies (above 8 GHz), primarily because, as frequency increases (especially in a millimeter-wave band), the insertion loss of the switch becomes excessive, and the insertion loss of the phase shift unit worsens, particularly at a phase of 180 degrees. The second implementation utilizes inductors to achieve the phase shift function. Similarly, this type of digital phase shifter faces challenges at high frequencies, mainly due to increased induction loss and pronounced impact of parasitic capacitance on the performance as frequency increases (especially in the millimeter-wave band).

Current implementations of the digital attenuator typically employ a single-ended switch to toggle a resistive attenuation network. However, this type of digital attenuator exhibits significant performance degradation at high frequencies (particularly above 8 GHz), primarily due to excessive insertion loss in the switch as frequency increases (especially in the millimeter-wave band). Furthermore, when a large attenuation value (e.g., 16 dB) is required, additional switch stacks need be engaged to enable the channel, which necessitates a larger layout and exacerbates insertion loss.

The existing digital phase shifter and digital attenuator employ separate architectures, typically implemented as discrete circuits that one dedicated to digital phase shifting and another for digital attenuation. This approach results in cumulative insertion loss equal to the sum of losses of both components for the system, increased control bit requirements, and greater application-level implementation complexity.

The phase shift attenuation circuit disclosed in the present disclosure is constructed based on a differential circuit architecture, and is capable of simultaneously realizing phase shift and attenuation functions, while achieving miniaturization and high performance.

Some preferred embodiments of the present disclosure are described below. It should be noted that the following description is for illustrative purposes and is not intended to limit the scope of protection of the present disclosure. The steps dealt with in the present disclosure may be performed in an exact sequence, or, alternatively, the various steps may be dealt with in reverse order or simultaneously. Also, other operations may be added to these processes, or a step or number of steps may be removed from these processes.

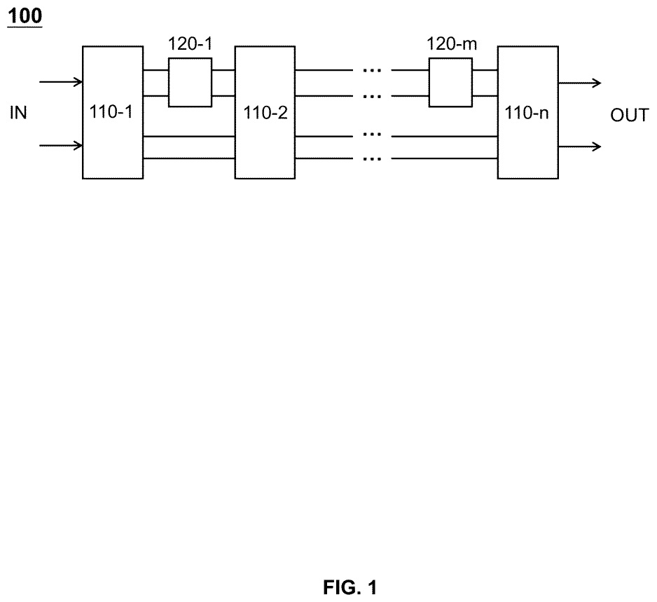

FIG. 1 is a schematic structural diagram illustrating a phase shift attenuation circuit according to some embodiments of the present disclosure.

In some embodiments, as illustrated in FIG. 1, a phase shift attenuation circuit 100 may include a plurality of first differential circuits 110-1, 110-2, . . . , and 110-n electrically connected in sequence. An electrical connection between any two adjacent first differential circuits of the plurality of first differential circuits may include at least one of a straight-through connection or a connection through an attenuator unit (e.g., including an attenuator unit 120-1, . . . , an attenuator unit 120-m). Values of n and m may be any positive integer. In some embodiments, as shown in FIG. 1, the first differential circuits 110-2 and 110-n−1 may all be directly connected with each other, or connected through the attenuator unit (e.g., including the attenuator unit 120-1, . . . , the attenuator unit 120-m−1).

The first differential circuit is a circuit that has a characteristic of “suppressing common mode signal and amplifying a differential mode signal”.

The attenuator unit is a circuit configured to reduce an intensity of an output signal of the first differential circuit without significantly changing a waveform or frequency characteristic of the output signal of the first differential circuit.

In some embodiments, each of the plurality of first differential circuits may include one or more first differential input ports, one or more first differential output ports, and a plurality of switching tube chips. One of the plurality of switching tube chips may be connected between a positive and negative interface of each of the one or more first differential input ports and a positive and negative interface of each of the one or more first differential output ports.

The switching tube chip refers to a semiconductor device used to control on/off of an RF signal. In an RF front-end module, the switching tube chip is mainly used to switch between different frequency bands or different communication modes to achieve multi-frequency band and multi-mode communication functions. A common switching tube chip is usually composed of a PIN diode or a gallium arsenide field-effect transistor (GaAs FET).

For the convenience of illustration, taking each of the plurality of first differential circuits having one first differential input port and one first differential output port as an example, the first differential input port may include a first positive interface and a first negative interface, and the first differential output port may include a second positive interface and a second negative interface. One of the plurality of switching tube chips is connected between the first positive interface and the second positive interface and between the first positive interface and the second negative interface, respectively, and one of the plurality of switching tube chips is connected between the first negative interface and the second positive interface and between the first negative interface and the second negative interface, respectively, for a total of four switching tube chips. A count of the switching tube chips varies as a count of the first differential input port and the first differential output port increases or decreases.

In some embodiments, connection or disconnection between the one or more first differential input ports and the one or more first differential output ports may be achieved by the switching tube chips to determine the electrical connection between the two adjacent first differential circuits. As shown in FIG. 1, the first first differential circuit 110-1 has one first differential input port and two first differential output ports. The switching of the switching tube chips determines whether the signal: (1) is transmitted through an upper first differential output port of the first differential circuit 110-1 to the attenuator unit 120-1 for amplitude attenuation before outputting to the second first differential circuit 110-2, or (2) is transmitted through a lower first differential output port of the first differential circuit 110-1 directly to the second first differential circuit 110-2.

The following is an exemplary illustration of the first differential circuits.

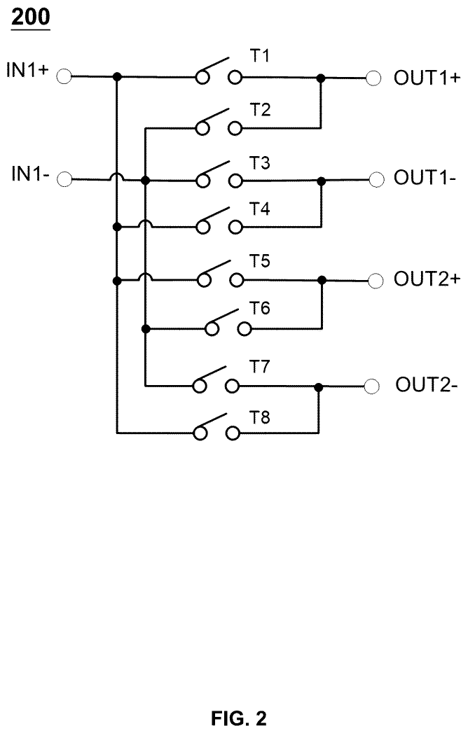

FIG. 2 is a schematic structural diagram illustrating a differential circuit according to some embodiments of the present disclosure.

In some embodiments, as shown in FIG. 2, a first differential circuit 200 includes a first differential input port (composed of a positive interface IN1+ and a negative interface IN1−) and two first differential output ports (composed of a positive interface OUT1+ and a negative interface OUT1−, and a positive interface OUT2+ and a negative interface OUT2−, respectively). A switching tube chip is connected between a positive and negative interface of the first differential input port and a positive and negative interface of each of the two first differential output ports. The switching tube chip includes a first switching tube chip T1, a second switching tube chip T2, a third switching tube chip T3, a fourth switching tube chip T4, a fifth switching tube chip T5, a sixth switching tube chip T6, a seventh switching tube chip T7, and an eighth switching tube chip T8. Input terminals of the first switching tube chip T1, the fourth switching tube chip T4, the fifth switching tube chip T5, and the eighth switching tube chip T8 are coupled and jointly connected to the positive interface IN1+. Input terminals of the second switching tube chip T2, the third switching tube chip T3, the sixth switching tube chip T6, and the seventh switching tube chip T7 are coupled and jointly connected to the negative interface IN1−. Output terminals of the first switching tube chip T1 and the second switching tube chip T2 are coupled and jointly connected to the positive interface OUT1+. Output terminals of the third switching tube chip T3 and the fourth switching tube chip T4 are coupled and jointly connected to the negative interface OUT1−. Output terminals of the fifth switching tube chip T5 and the sixth switching tube chip T6 are coupled and jointly connected to the positive interface OUT2+. Output terminals of the seventh switching tube chip T7 and the eighth switching tube chip T8 are coupled and jointly connected to the negative interface OUT2−.

In some embodiments, in the first differential circuit 200, connection or disconnection between the positive and negative interface of the first differential input port and the positive and negative interface of each of the two first differential output ports may be achieved by setting a power supply voltage of each switching tube chip to determine whether the electrical connection between the two adjacent first differential circuits is the straight-through connection or the connection through the attenuator unit. For example, if a power supply voltage of the first switching tube chip T1 and the third switching tube chip T3 is V1, a power supply voltage of the second switching tube chip T2, the fourth switching tube chip T4, the fifth switching tube chip T5, the sixth switching tube chip T6, the seventh switching tube chip T7, and the eighth switching tube chip T8 is −V1. If V1 is a positive voltage (i.e., V1>Vth, Vth is a gate threshold voltage), the positive interface IN1+ and the positive interface OUT1+ are connected, the negative interface IN1− and the negative interface OUT1− are connected, the positive interface IN1+ and the positive interface OUT2+ are disconnected, and the negative interface IN1− and the negative interface OUT2− are disconnected. If a power supply voltage of the fifth switching tube chip T5 and the seventh switching tube chip T7 is set to V1, a power supply voltage of the first switching tube chip T1, the second switching tube chip T2, the third switching tube chip T3, the fourth switching tube chip T4, the sixth switching tube chip T6, and the eighth switching tube chip T8 is −V1. If V1 is a positive voltage (i.e., V1>Vth), the positive interface IN1+ and the positive interface OUT2+re connected, the negative interface IN1− and the negative interface OUT2− are connected, the positive interface IN1+ and the positive interface OUT1+ are disconnected, and the negative interface IN1− and the negative interface OUT1− are disconnected.

Accordingly, when an input signal (e.g. a differential signal) is input from the positive interface IN1+ and the negative interface IN1−, the signal is enabled to be output from the positive interface OUT1+ and the negative interface OUT1−, or the positive interface OUT2+ and the negative interface OUT2− by setting the power supply voltage of the switching tube chip. Assuming that the first differential circuit 200 is the first first differential circuit 110-1 of the phase shift attenuation circuit 100, and that the positive interface OUT1+ and the negative interface OUT1− are connected to the attenuator unit 120-1 and the positive interface OUT2+ and the negative interface OUT2− are connected to the second first differential circuit 110-2, the above power supply voltage is supplied to the switching tube chip to make the differential signal be output from the positive interface OUT1+ and the negative interface OUT1− to pass through the attenuator unit 120-1, thereby making the electrical connection between the first differential circuit 110-1 and the adjacent second first differential circuit 110-2 be the connection through the attenuator unit; or the signal is output from the positive interface OUT2+ and the negative interface OUT2− and directly input to a next differential circuit, thereby making the electrical connection between the first differential circuit 110-1 and the adjacent second first differential circuit 110-2 be the straight-through connection.

In some embodiments, the first differential circuit 200 may adjust an insertion loss and isolation by adjusting a size of the switching tube chip and resistance of each terminal. Adjusting the size of the switching tube chip may involve adjusting a Ron value (i.e., on-resistance of the switching tube chip) of the switching tube chip in an on-state condition. When the switching tube chip is on, the insertion loss of the switching tube chip is determined by both the Ron value and a Rds value (i.e., drain-to-source resistance), i.e., Ron is connected in parallel with Rds. Rgs (i.e., gate-to-source resistance) affects a voltage of a switching field effect transistor, indicating that the insertion loss of the switch differs at various voltages.

In some embodiments of the present disclosure, the insertion loss and a device size may be considered by adjusting the size of the switching tube chip and the resistance of each terminal. Meanwhile, since the smaller the switching off capacitance, the smaller the size, and the better the isolation, the isolation of the differential circuit may be by adjusting the size of the switching tube chip. Accordingly, the first differential circuit 200 may be set to exhibit high isolation and low insertion loss, thereby enabling the device to possess the advantages of small size, high isolation, and low insertion loss, which in turn facilitates higher accuracy in phase shifting.

In some embodiments of the present disclosure, the first differential circuit 200 may reduce a return loss by connecting a matching circuit. For example, the matching circuit may include an input matching circuit and an output matching circuit, and the input matching circuit and the output matching circuit may be matched and connected with the first differential input port and the first differential output port, respectively, by a coupling line. The return loss of the first differential input port and the first differential output port may be adjusted by adjusting one or more of an even-mode impedance, an odd-mode impedance, or an electrical length that characterizes the coupling line. Adjusting the even-mode impedance and the odd-mode impedance is essentially to adjust the differential impedance of a port, and the impedance of the port affects the return loss, which in turn adjusts the return loss. At RF and microwave frequencies, different electrical lengths exhibit different impedances, and the impedance of the port can be adjusted by changing the electrical length. The matching circuit refers to a circuit that achieves impedance matching. The matching circuit guarantees that the signal or energy is efficiently transmitted from a source terminal to a load terminal while minimizing reflection and loss.

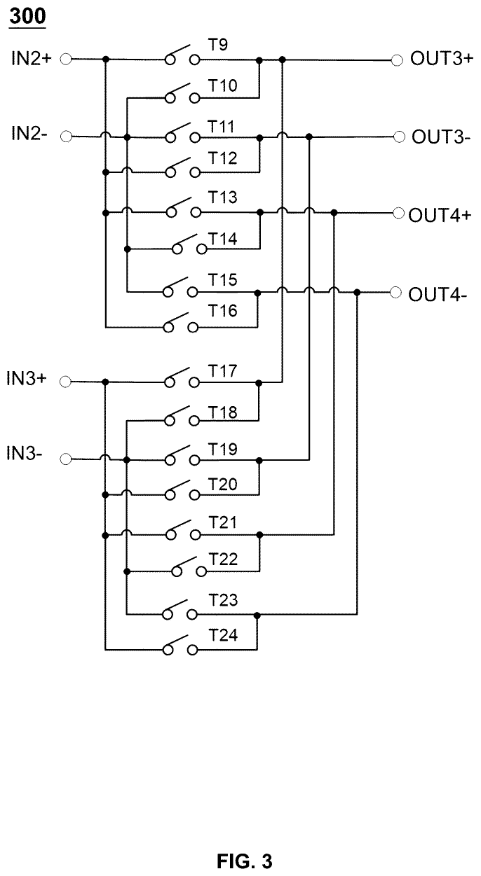

FIG. 3 is a schematic structural diagram illustrating a differential circuit according to some embodiments of the present disclosure.

In some embodiments, as shown in FIG. 3, a first differential circuit 300 may include two first differential input ports composed of a positive interface IN2+ and a negative interface IN2−, and a positive interface IN3+ and a negative interface IN3−, respectively. The first differential circuit 300 may include may include two first differential output ports composed of a positive interface OUT3+ and a negative interface OUT3−, and a positive interface OUT4+ and a negative interface OUT4−, respectively. A switching tube chip may be connected between a positive and negative interface of each of the two first differential input ports and a positive and negative interfaces of each of the two first differential output ports. The switching tube chip includes a ninth switching tube chip T9, a tenth switching tube chip T10, an eleventh switching tube chip T11, a twelfth switching tube chip T12, a thirteenth switching tube chip T13, a fourteenth switching tube chip T14, a fifteenth switching tube chip T15, a sixteenth switching tube chip T16, a seventeenth switching tube chip T17, an eighteenth switching tube chip T18, a nineteenth switching tube chip T19, a twentieth switching tube chip T20, a twenty-first switching tube chip T21, a twenty-second switching tube chip T22, a twenty-third switching tube chip T23, and a twenty-fourth switching tube chip T24. Input terminals of the ninth switching tube chip T9, the twelfth switching tube chip T12, the thirteenth switching tube chip T13, and the sixteenth switching tube chip T16 are coupled and jointly connected to the positive interface IN2+. Input terminals of the tenth switching tube chip T10, the eleventh switching tube chip T11, the fourteenth switching tube chip T14, and the fifteenth switching tube chip T15 are coupled and jointly connected to the negative interface IN2−. Input terminals of the seventeenth switching tube chip T17, the twentieth switching tube chip T20, the twenty-first switching tube chip T21, and the twenty-fourth switching tube chip T24 are coupled and jointly connected to the positive interface IN3+. Input terminals of the eighteenth switching tube chip T18, the nineteenth switching tube chip T19, the twenty-second switching tube chip T22, and the twenty-third switching tube chip T23 are coupled and jointly connected to the negative interface IN3−. Output terminals of the ninth switching tube chip T9, the tenth switching tube chip T10, the seventeenth switching tube chip T17, and the eighteenth switching tube chip T18 are coupled and jointly connected to the positive interface OUT3+. Output terminals of the eleventh switching tube chip T11, the twelfth switching tube chip T12, the nineteenth switching tube chip T19, and the twentieth switching tube chip T20 are coupled and connected to the negative interface OUT3−. Output terminals of the thirteenth switching tube chip T13, the fourteenth switching tube chip T14, the twenty-first switching tube chip T21, and the twenty-second switching tube chip T22 are coupled and jointly connected to the positive interface OUT4+. Output terminals of the fifteenth switching tube chip T15, the sixteenth switching tube chip T16, the twenty-third switching tube chip T23, and the twenty-fourth switching tube chip T24 are coupled and jointly connected to the negative interface OUT4−.

In some embodiments, in the first differential circuit 300, connection or disconnection between the positive and negative interfaces of the first differential input ports and the first differential output ports may be achieved by setting a power supply voltage of each switching tube chip to determine whether an electrical connection between two adjacent differential circuits is a straight-through connection or a connection through an attenuator unit.

For example, if a power supply voltage of the ninth switching tube chip T9, the eleventh switching tube chip T11, the twenty-first switching tube chip T21, and the twenty-third switching tube chip T23 is set to V2, a power supply voltage of the tenth switching tube chip T10, the twelfth switching tube chip T12, the twentieth switching tube chip T20, the twenty-second switching tube chip T22, and the twenty-fourth switching tube chip T24 is −V3. If V3 is a positive voltage (i.e., V3>Vth), the positive interface IN2+ and the positive interface OUT3+ are connected, the negative interface IN2− and the negative interface OUT3− are connected, the positive interface IN3+ and the positive interface OUT4+ are connected, the negative interface IN3− and the negative interface OUT4− are connected, the positive interface IN2+ and the positive interface OUT4+ are disconnected, the negative interface IN2− and the negative interface OUT4− are disconnected, the positive interface IN3+ and the positive interface OUT3+ are disconnected, and the negative interface IN3− and the negative interface OUT3− are disconnected. If a power supply voltage of the thirteenth switching tube chip T13, the fifteenth switching tube chip T15, the seventeenth switching tube chip T17, and the nineteenth switching tube chip T19 is set to V3, a power supply voltage of the tenth switching tube chip T10, the eleventh switching tube chip T11, the twelfth switching tube chip T12, the fourteenth switching tube chip T14, the sixteenth switching tube chip T16, the eighteenth switching tube chip T18, and the twentieth switching tube chip T20 to the twenty-fourth switching tube chip T24 is −V3. If V3 is a positive voltage (i.e., V3>Vth), the positive interface IN2+ and the positive interface OUT4+ are connected, the negative interface IN2− and the negative interface OUT4− are connected, the positive interface IN3+ and the positive interface OUT3+ are connected, the negative interface IN3− and the negative interface OUT3− are connected, the positive interface IN2+ and the positive interface OUT3+ are disconnected, the negative interface IN2− and the negative interface OUT3− are disconnected, the positive interface IN3+ and the positive interface OUT4+ are disconnected, and the negative interface IN3− and the negative interface OUT4− are disconnected.

In some embodiments, when an input signal (e.g., a differential signal) is input from the interfaces IN2+ and IN2− or the interfaces IN3+ and IN3− (e.g., input from a previous first differential circuit through the straight-through connection or input after attenuation through the attenuator unit), the signal is enabled to be output from the interfaces OUT3+ and OUT3− or the interfaces OUT4+ and OUT4− by setting the power supply voltage to the switching tube chip. Assuming that the first differential circuit 300 is the second first differential circuit 110-2 of the phase shift attenuation circuit 100, the interfaces IN2+ and IN2− may be connected to the attenuator unit 120-1, and the interfaces IN3+ and IN3− may be connected to the first differential circuit 110-1 for receiving the input differential signal. Which interface receives the differential signals is determined based on the output of the preceding first differential circuit 110-1, which may be found in the present disclosure above. The interfaces OUT3+ and OUT3− are followed by the attenuator unit, and the interfaces OUT4+ and OUT4− are followed by the third first differential circuit, the power supply voltage is supplied to the switching tube chip to make the differential signal be output from the interfaces OUT3+ and OUT3− to pass through the attenuator unit, or output from the interfaces OUT4+ and OUT4− outputs directly into a next differential circuit.

In some embodiments of the present disclosure, the above first differential circuit 300 may adjust the isolation and the insertion loss of the circuit by adjusting a size of the switching tube chip and resistance of each terminal. High isolation and low insertion loss of the first differential circuit 300 may be achieved. A device to which the first differential circuit 300 is applied also possesses the advantages of small size, high isolation, and low insertion loss, which achieves phase shifting with higher accuracy. In addition, the first differential circuit 300 may reduce a return loss by connecting a matching circuit. More descriptions may be found in the related descriptions of the first differential circuit 200, which are not repeated here.

In some embodiments, the phase shift attenuation circuit 100 may realize 8-bit step attenuation by the attenuator unit, and 7-bit step attenuation included in the 8-bit step attenuation may be configured to realize a phase shift function. In some embodiments, lower 7-bit step attenuation may realize the phase shift function. For example, by selecting straight-through in an 8th bit, first 7 bits enable phase shifting by controlling an attenuation value of an amplitude.

In some embodiments, the 8-bit step attenuation may be configured to implement phase shifting and attenuation. For example, the first 7 bits implement phase shifting by controlling the attenuation value of the amplitude, and the 8th bit implements amplitude attenuation while keeping the phase constant. An attenuation range of the 7-bit step attenuation may be in a range of 0-31.75 dB, which achieves the 8-bit step attenuation in an attenuation range of 0-63.75 dB by adding one bit of attenuation (e.g., 32 dB).

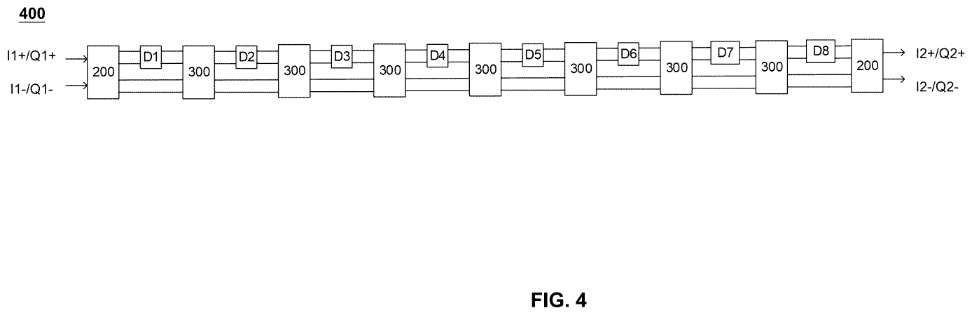

FIG. 4 is a schematic structural diagram illustrating a phase shift attenuation circuit according to some embodiments of the present disclosure.

In some embodiments, a plurality of first differential circuits may be identical and/or different.

As shown in FIG. 4, a phase shift attenuation circuit 400 may include two first differential circuits 200 and seven first differential circuits 300. The seven first differential circuits 300 are connected in sequence between the two first differential circuits 200. An attenuator unit is provided between two adjacent first differential circuits, for a total of eight attenuator units. According to a direction of signal transmission, an attenuator unit D1 achieves 32 dB attenuation, the, an attenuator unit D2 achieves 16 dB attenuation, an attenuator unit D3 achieves 8 dB attenuation, an attenuator unit D4 achieves 4 dB attenuation, an attenuator unit D5 achieves 2 dB attenuation, an attenuator unit D6 achieves 1 dB attenuation, an attenuator unit D7 achieves 0.5 dB attenuation, and an attenuator unit D8 achieves 0.25 dB attenuation.

In some embodiments, 7-bit step attenuation (e.g., D2-D8) enables phase shifting in a range of 0 deg-90 deg. For example, an 8th bit selects straight-through connection (i.e., without passing through the attenuator unit D1), and the phase shifting in the range 0 deg-90 deg is then realized based on an attenuation range of 0-31.75 dB.

In some embodiments, the 8-bit step attenuation (e.g., D1-D8) may realize phase shifting in a range of 0 deg-90 deg and amplitude attenuation. For example, an 8th bit is enabled to realize a attenuation range of 0-63.75 dB, where the phase shifting in the range of 0 deg-90 deg is realized in an attenuation range of 0-31.75 dB, and the amplitude attenuation is realized in an attenuation range of 31.75 dB-63.75 dB.

In some embodiments of the present disclosure, the phase shift attenuation circuit is designed based on the differential circuit architecture and has the characteristics of small size and high bandwidth. The phase shifting and attenuation functions are realized through multi-bit attenuator units, which is simple in logic control. In addition, smaller insertion loss, higher bandwidth, and better performance can be realized based on the characteristics of the differential circuit.

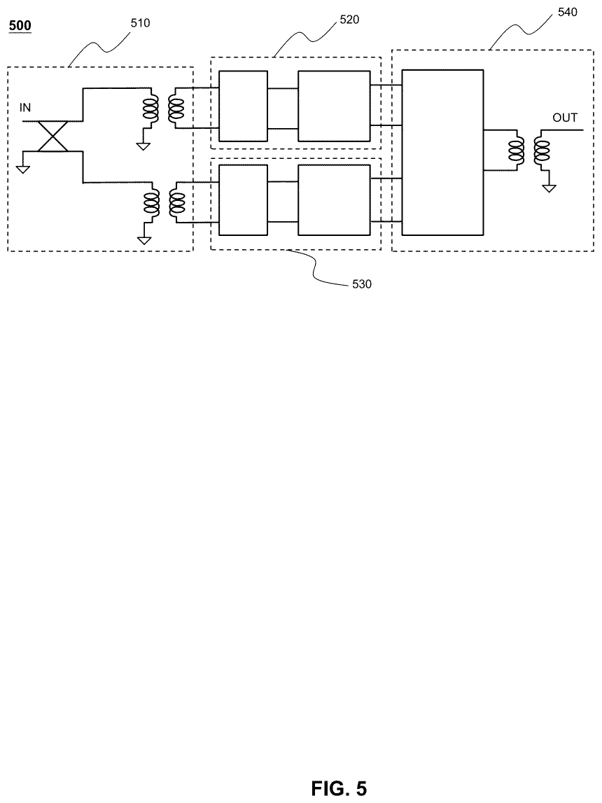

FIG. 5 is a schematic structural diagram illustrating a phase shift attenuation network according to some embodiments of the present disclosure.

In some embodiments, a phase shift attenuation network may include any phase shift attenuation circuit of FIGS. 1-4.

In some embodiments, as shown in FIG. 5, a phase shift attenuation network 500 may include a first node circuit 510, a second node circuit 540, and a first signal channel 520 and a second signal channel 530 which are coupled between the first node circuit 510 and the second node circuit 540. In some embodiments, the first node circuit 510 and the second node circuit 540 may include a phase shift attenuation circuit, respectively. The phase shift attenuation circuit may be the phase shift attenuation circuit as shown in FIG. 1.

In some embodiments, an input signal input into the phase shift attenuation network 500 may enter from the first node circuit 510 to be split into a pair of quadrature signals. For example, the pair of quadrature signals includes an in-phase signal I (or referred to as an I-channel signal) and an quadrature signal Q (or referred to as a Q-channel signal). The I/Q signals are of the same frequency but 90° out of phase. The pair of quadrature signals may be simultaneously output to the first signal channel 520 and the second signal channel 530 to perform a signal attenuation and/or quadrant conversion to achieve attenuation and/or phase shifting. For example, the I-channel signal may be input into the first signal channel 520 for processing and the Q-channel signal may be input into the second signal channel 530 for processing.

In some embodiments of the present disclosure, the first signal channel 520 and the second signal channel 530 may be implemented based on an architecture of a differential circuit. Accordingly, the quadrature signals (i.e., the I-channel signal and the Q-channel signal) are processed to generate a pair of differential signals, respectively. For example, a first pair of differential signals are input into the first signal channel 520 for processing and a second pair of differential signals are input into the second signal channel 530 for processing. In an implementable embodiment, an exemplary circuit structure for this differential circuit may be a switching tube chip connected between each of positive and negative interfaces of input and output ports. The circuit structure reduces the insertion loss, enhances interference resistance, and realizes the requirements of high performance and small size of the device based on the switching tube chip. That is to say, the device utilizing the first signal channel 520 and the second signal channel 530 constructed based on the differential circuit can achieve high isolation while reducing the size of the device and the insertion loss. The first signal channel 520 and the second signal channel 530 can perform signal attenuation and/or quadrant conversion on the input pair of differential signals to achieve phase shifting and amplitude attenuation of the input signal. For example, the first signal channel 520 and the second signal channel 530 may include a phase shift attenuation circuit and/or a quadrant conversion circuit, respectively. For example, the phase shift attenuation circuit may be the phase shift attenuation circuit 100 as described above. The quadrant conversion circuit may realize quadrant conversion through connection and disconnection between the positive and negative interfaces of the input and output ports of the differential circuit. For example, one of four quadrants of the quadrant conversion circuit is selected, where the four quadrants include a first quadrant (0 deg-90 deg), a second quadrant (90 deg-180 deg), a third quadrant (180 deg-270 deg), and a fourth quadrant (270 deg-360 deg). An initial phase is obtained through phase shifting based on the phase shift attenuation circuit and quadrant selection based on the quadrant conversion circuit, thereby realizing phase shifting in a range of 0-360 deg.

The second node circuit 540 may be configured to perform vector synthesis on a first phase shift signal output by the first signal channel 520 and a second phase shift signal output by the second signal channel 530. In an implementable embodiment, the second node circuit 540 may be constructed using differential coupling. The insertion loss can be reduced and the isolation can be improved through the design of the electrical length of the coupling line and improvements in the input or output ports. Output signals output from the second node circuit 540 may be the pair of differential signal or single-ended signals. For example, the differential signals are converted into the single-ended signals to be output by the device.

The following is an exemplary illustration of the various components of the phase shift attenuation network 500. It should be noted that the following description is not limiting.

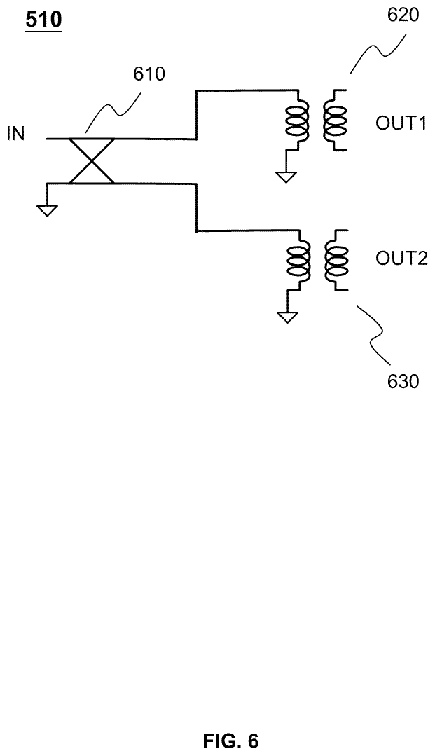

FIG. 6 is a schematic structural diagram illustrating a first node circuit according to some embodiments of the present disclosure.

In some embodiments, as shown in FIG. 6, the first node circuit 510 may include a signal processor 610 and a first transformer 620 and a second transformer 630 which are electrically connected with two output terminals of the signal processor 610, respectively. The signal processor 610 may be any electronic component capable of implementing a signal splitting function with a 90° phase difference. For example, the signal processor 610 may include a hybrid coupler, a quadrature coupler, a 90° bridge, etc. Taking the signal processor 610 being a 90° bridge as an example, the signal processor 610 includes a single-ended input port IN and two output ports. Port impedance of the single-ended input port may be 50 ohm. An input signal enters from the single-ended input port IN to be processed to output a pair of quadrature signals, i.e., an I-channel signal and a Q-channel signal. The pair of quadrature signals are output from the two output ports to the first transformer 620 and the second transformer 630, respectively. The first transformer 620 and the second transformer 630 convert the quadrature signals into differential signals using a coil inductive characteristic (e.g., a center-tapped winding) and then output from output terminals OUT1 and OUT2. For example, the first transformer 620 may be configured to process the I-channel signal to output differential signals I1+ and I1− at the output terminal OUT1. The second transformer 630 may be configured to process the Q-channel signal to output second differential signals Q1+ and Q1− at the output terminal OUT2.

In some embodiments, the first signal channel 520 and the second signal channel 530 may include the phase shift attenuation circuit 100/400 as described above and the quadrant conversion circuit connected to the phase shift attenuation circuit 100. More descriptions regarding the phase shift attenuation unit 100/400 may be found in the present disclosure above.

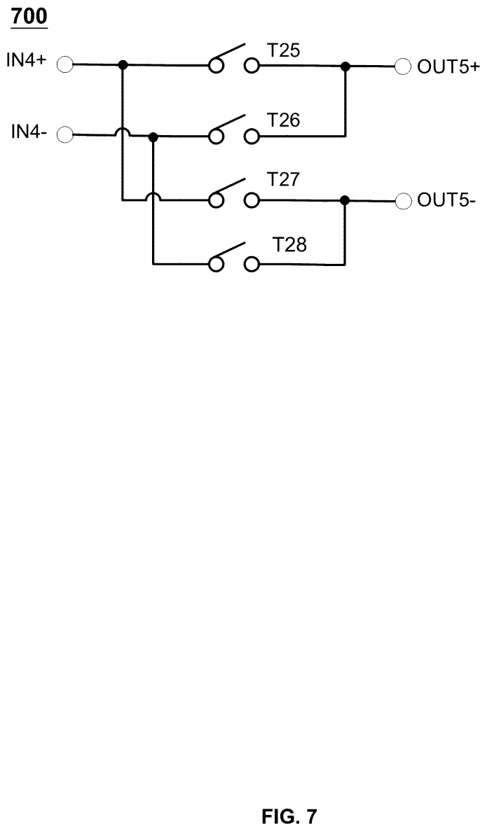

FIG. 7 is a schematic structural diagram illustrating a quadrant conversion circuit according to some embodiments of the present disclosure.

In some embodiments, a first node circuit and a second node circuit may further include a quadrant conversion circuit electrically connected with the phase shift attenuation circuit 100/400. In some embodiments, the quadrant conversion circuit may be constructed based on a second differential circuit. The second differential circuit refers to another differential circuit different from a first differential circuit. In some embodiments, the second differential circuit may realize quadrant conversion of a phase by connection or disconnection between a positive and negative interface of the second differential input port and a positive and negative interface of a second differential output port, and realizes phase shifting in a preset range based on the phase shift attenuation circuit.

The preset range is a preset range of phase shifting of the first node circuit and the second node circuit. The preset range may be expressed as a large range. The large range may be, for example, 0-90°, 0-180°, 0-270°, or 0-360°.

In some embodiments, the phase shifting of the first node circuit or the second node circuit may be in a range of 0 deg-360 deg.

As shown in FIG. 7, a second differential circuit 700 may include a second differential input port composed of a positive interface IN4+ and a negative interface I4− and a second differential output port composed of a positive interface OUT5+ and a negative interface OUT5−. A switching tube chip may be connected between positive and negative interfaces of the second differential input port and the second differential output port. The switching tube chip may include a twenty-fifth switching tube chip T25, a twenty-sixth switching tube chip T26, a twenty-seventh switching tube chip T27, and a twenty-eighth switching tube chip T28. An input terminal of the twenty-fifth switching tube chip T25 and an input terminal of the twenty-seventh switching tube chip T27 are coupled and jointly connected to the positive interface IN4+. An input terminal of the twenty-sixth switching tube chip T26 and an input terminal of the twenty-eighth switching tube chip T28 are coupled and jointly connected to the negative interface IN4−. An output terminal of the twenty-fifth switching tube chip T28 and an output terminal of the twenty-sixth switching tube chip T26 are coupled and jointly connected to the positive interface OUT5+. An output terminal of the twenty-seventh switching tube chip T27 and an output terminal of the twenty-eighth switching tube chip T28 are coupled and jointly connected to the negative interface OUT5−.

In some embodiments of the present disclosure, the second differential circuit 700 may adjust the isolation and the insertion loss by adjusting a size of the switching tube chip and the resistance of each terminal, and reduce the return loss by connecting a matching circuit. Specific embodiments may be found in the related descriptions of the first differential circuit described above.

In some embodiments, in the second differential circuit 700, connection or disconnection between the positive and negative interfaces of the second differential input port and the second differential output port may be achieved by setting a power supply voltage of each switching tube chip to realize a state change of the second differential circuit 700. Combinations of different states of the two second differential circuits 700 (e.g., included in the first signal channel 520 and the second signal channel 530, respectively) configured to process the I-channel signal and the Q-channel signal, respectively can realize quadrant conversion, thereby changing an initial phase of a first differential signal and a second differential signal output after processing of the phase shift attenuation circuit 100/400. The phase shift attenuation network 600 realizes the phase shifting in a range of 0-360° based on the phase shifting in a range of 0 deg-90 deg and the change in the initial phase of the quadrant conversion circuit.

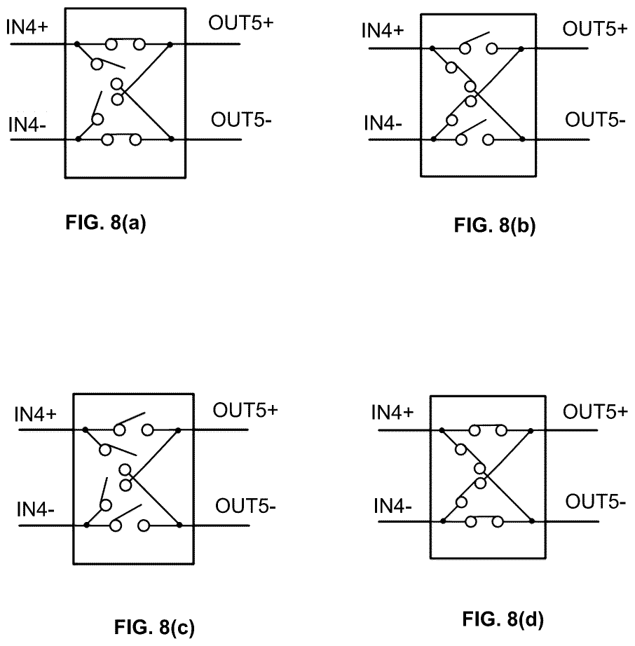

For example, the second differential circuit 700 may have four states, as illustrated with reference to FIG. 8(a), FIG. 8(b), FIG. 8(c), and FIG. 8(d).

FIG. 8(a) is a schematic diagram illustrating an exemplary connection state of the third differential circuit 700 constituting a quadrant conversion circuit according to some embodiments of the present disclosure.

FIG. 8(b) is a schematic diagram illustrating an exemplary connection state of the third differential circuit 700 constituting a quadrant conversion circuit according to some embodiments of the present disclosure.

FIG. 8(c) is a schematic diagram illustrating an exemplary connection state of the third differential circuit 700 constituting a quadrant conversion circuit according to some embodiments of the present disclosure.

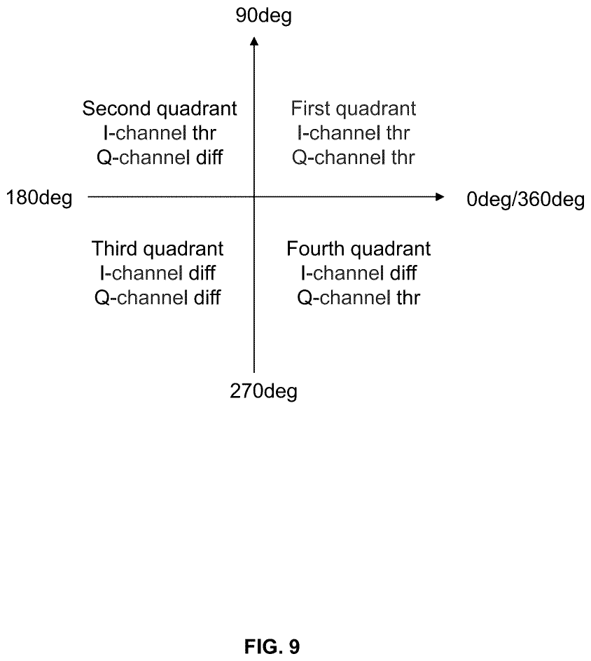

FIG. 8(d) is a schematic diagram illustrating an exemplary connection state of the third differential circuit 700 constituting a quadrant conversion circuit according to some embodiments of the present disclosure. FIG. 9 is a schematic diagram illustrating an exemplary correspondence characteristic between a quadrant and a connection state of a differential circuit according to some embodiments of the present disclosure.

As shown in FIGS. 8(a)-8(d), FIGS. 8(a)-8(d) are schematic diagrams illustrating states of the third differential circuit 700, including a straight-through state (thr) (as shown in FIG. 8(a)), a differential state (diff) (as shown in FIG. 8(b)), an open state (open) (as shown in FIG. 8(c)), and a short circuit state (short) (shown in FIG. 8(d)). In the straight-through state (thr), the positive interface IN4+ and the positive interface OUT5+ are connected, the negative interface IN4− and the negative interface OUT5− are connected, the positive IN4+ and the positive interface OUT5+ are disconnected, and the negative interface IN4− and the positive interface OUT5+ are disconnected. In the differential state (diff), the positive interface IN4+ and the positive interface OUT5+ are disconnected, the positive interface IN4− and the negative interface OUT5− are disconnected, the positive interface IN4+ and the positive interface OUT5+ are connected, and the negative interface IN4− and the positive interface OUT5+ are connected. In the open state (open), the positive interface IN4+ and the positive interface OUT5+ are disconnected, the negative interface IN4− and the negative interface OUT5− are disconnected, the positive interface IN4+ and the positive interface OUT5+ are disconnected, and the negative interface IN4− and the positive interface OUT5+ are disconnected. In the short circuit state (short), the positive interface IN4+ and the positive interface OUT5+ are connected, the negative interface IN4− and the negative interface OUT5− are connected, the positive interface IN4+ and the positive interface OUT5+ are connected, and the negative interface IN4− and the positive interface OUT5+ are connected.

Selection of the four quadrants may be achieved by combining the states of the two second differential circuits 700 included in the first signal channel 520 and the second signal channel 530. For example, when the state of the second differential circuit 700 in the first signal channel 520 for processing the I-channel signal is in the straight-through state (thr), and the state of the second differential circuit in the second signal channel 530 for processing the Q-channel signal is in the straight-through state (thr), it indicates a first quadrant Q1 (0 deg-90 deg). When the state of the second differential circuit 700 in the first signal channel 520 for processing the I-channel signal is in the straight-through state (thr), and the state of the second differential circuit in the second signal channel 530 for processing the Q-channel signal is in the differential state (diff), it indicates a second quadrant Q2 (90 deg-180 deg). When the state of the second differential circuit 700 in the first signal channel 520 for processing the I-channel signal is in the differential state (diff), and the state of the second differential circuit in the second signal channel 530 for processing the Q-channel signal is in the differential state (diff), it indicates a third quadrant Q3 (180 deg-270 deg). When the state of the second differential circuit 700 in the first signal channel 520 for processing the I-channel signal is in the differential state (diff), and the state of the second differential circuit in the second signal channel 530 for processing the Q-channel signals is in the straight-through state (thr), it indicates a fourth quadrant Q4 (270 deg-360 deg). The open state (open) may be configured to implement a device to which the open state (open) is applied. For example, an off state of a phase shifter, and the short circuit state (short) may be configured to implement a short circuit in a device (e.g., the phase shifter) to which the off state and the short circuit state (short) are applied. The foregoing can be more clearly understood with reference to FIG. 9 illustrating an exemplary correspondence characteristic between the four quadrants and the connection state of the differential circuit according to some embodiments of the present disclosure.

Differential signals I1+ and I1−, or second differential signals Q1+ and Q1− output by the first node circuit 510 are input from the differential input port of the phase shift attenuation circuits 100/400 included in the first signal channel 520 or the second signal channel 530 (e.g., from the first differential input ports of the first differential circuits 200 disposed at a head and a tail, respectively), and processed by the phase shift attenuation circuit 100/400 to output differential signals I2+ and I2−, Q2+ and Q2− after amplitude attenuation and/or phase shifting (e.g., in the range of 0 deg-90 deg). The differential signals I2+ and I2− and the differential signals Q2+ and Q2− may be input into the second differential circuit 700 serving as a quadrant conversion circuit. For example, the differential signals are input from the interface IN4+ and IN4− of the second differential input port, and the interfaces OUT5+ and OUT5− of the second differential output port output differential signals I3+ and I3−, Q3+ and Q3− after quadrant conversion. The phase shifting in a range of 0-360 deg is realized by selection of the initial phase after the quadrant conversion and the phase shifting in a range of 0 deg-90 deg realized by amplitude attenuation. The differential signals I3+ and I3−, Q3+ and Q3− may be differential signals after amplitude attenuation and/or phase shifting, which are subsequently input to the second node circuit 540 for subsequent processing.

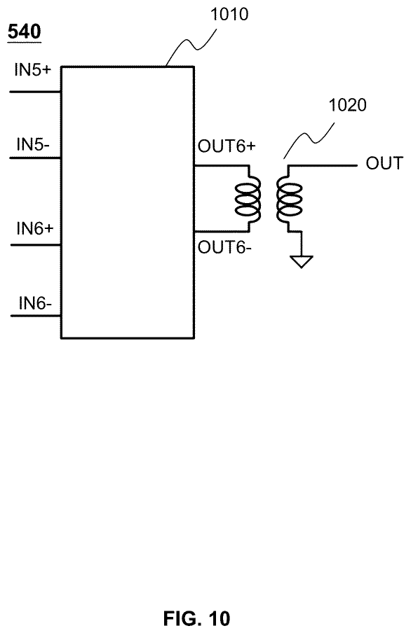

FIG. 10 is a schematic diagram illustrating an exemplary amplitude-phase correspondence according to some embodiments of the present disclosure.

In some embodiments, as shown in FIG. 10, the second node circuit 540 of the present disclosure may be configured to perform vector synthesis on the input differential signals I3+ and I3− and second phase shift signals Q3+ and Q3−. The second node circuit 540 may include a combiner 1010 constructed based on the differential circuit. The combiner is a device that combines signals from a plurality of sources into a single signal output. The combiner 1010 includes two third differential input ports consisting of interfaces IN5+ and IN5−, and interfaces IN6+ and IN6−, respectively, for receiving the differential signals I3+ and I3−, and the second phase shift signals Q3+ and Q3−, respectively. That is, the differential signals I3+ and I3− are input from the interfaces IN5+ and IN5−, and the differential signals Q3+ and Q3− are input from the interfaces IN6+ and IN6−. The combiner 1010 performs vector synthesis on the input signals and output a pair of synthesized differential signals (which are referred to as synthesized signals in the present disclosure) from a third differential output port (which is composed of interfaces OUT6+ and OUT6−). If the phase shift attenuation network 500 is applied to a differential system (e.g., to perform a differential operation on an input signal), the synthesized signal may be designated as an output signal after phase shifting. In some embodiments, the second node circuit 540 may further include a third transformer 1020. The third transformer 1020 may be electrically connected with the third differential output port of the combiner 1010 to convert the synthesized differential signals into a single-ended signal to be output from a single-ended output port OUT. This single-ended signal may be designated as the output signal after phase shifting.

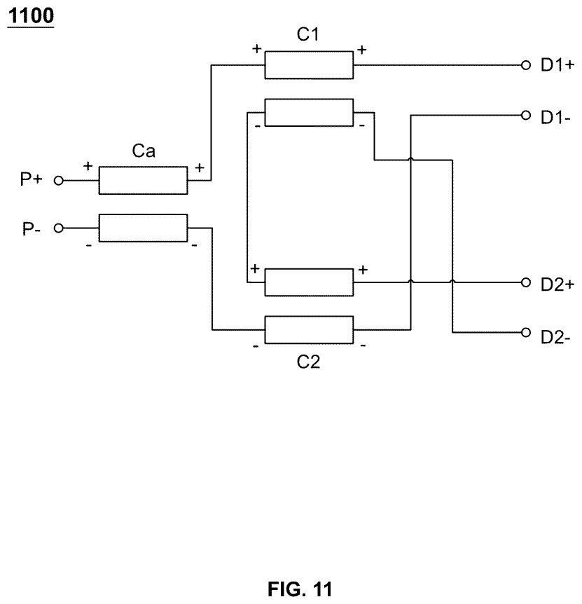

FIG. 11 is a schematic diagram illustrating different exemplary amplitudes according to some embodiments of the present disclosure.

In some embodiments, a second node circuit may include a third differential circuit. The third differential circuit refers to another differential circuit that is different from a first differential circuit and a second differential circuit. A third differential circuit 1100 shown in FIG. 11 may serve as the combiner 1010.

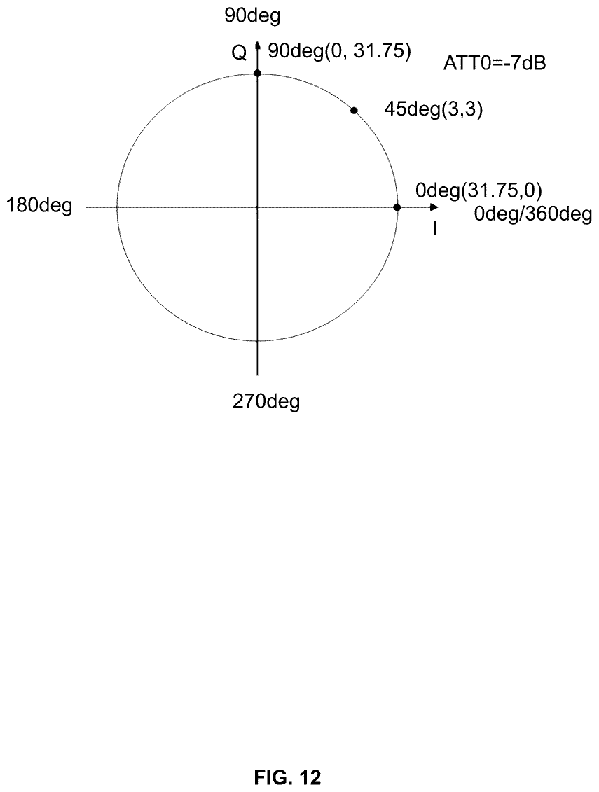

FIG. 12 is a schematic diagram illustrating exemplary S-parameters at different phases under the same amplitude according to some embodiments of the present disclosure.

In some embodiments, as shown in FIG. 12, the third differential circuit 1100 may include an input differential network, an input differential unit, an output differential unit, and an output differential network. The input differential network may include an input port composed of a first port P+ and a second port P−. The input differential unit may include an input differential coupling line Ca. A positive input terminal of the input differential coupling line Ca may be connected with the first port P+, and a negative input terminal of the input differential coupling line Ca may be connected with a second port P−. The output differential unit may include a first coupling line C1 and a second coupling line C2. A positive input terminal of the first coupling line C1 may be connected with a positive output terminal of the input differential coupling line Ca, and a negative input terminal of the second coupling line C2 may be connected with a negative output terminal of the input differential coupling line Ca. Meanwhile, a negative input terminal of the first coupling line C1 may be connected with a positive input terminal of the second coupling line C2. The output differential network may include a first output differential port and a second output differential port. A positive interface D1+ of the first output differential port may be connected with a positive output terminal of the first coupling line C1, and a negative interface D1− of the first output differential port may be connected with the negative output terminal of the second coupling line C2. A positive interface D2+ of the second output differential port may be connected with a positive output terminal of the second coupling line C2, and a negative interface D2− of the second output differential port may be connected with a negative output terminal of the first coupling line C1.

The first output differential port D1+/D1− of the third differential circuit 1100 may be used as one third differential input port IN5+/IN5− of the combiner 1010, and the second output differential port D2+/D2− may be used as another third differential input port IN6+/IN6− of the combiner 1010. The input differential network P+/P− of the third differential circuit 1100 may be used for the third differential output port OUT6+/OUT6− of the combiner 1010. The differential signals I3+ and I3− may be input from the first output differential port D1+/D1−, and the differential signals Q3+ and Q3− may be input from the second output differential port D2+/D2−. The third differential circuit 1200 may implement a vector synthesis function by outputting a pair of synthesized differential signals from the input differential network P+/P−.

In some embodiments, the first output differential port and the second output differential port of the output differential network may be configured to receive a first phase shift signal and a second phase shift signal, respectively. In some embodiments, the input differential network may be configured to output a synthesized signal.

In some embodiments of the present disclosure, the combiner 1010 constructed based on the third differential circuit 1100 enables a differential or combining function, and can modulate the isolation, the bandwidth characteristic, the insertion loss, and the return loss by adjusting the electrical length of the coupling line, the odd-mode impedance, and the even-mode impedance. The combiner 1010 is designed based on the differential coupling line, which can be adjusted to a wavelength much smaller than ¼ of the center frequency based on the adjustable electrical length of the coupling line, allowing for smaller size, lower insertion loss, and higher isolation. In addition, the use of the differential coupling line also makes the combiner 1010 possess high resistance to interference and high suppression performance to stray and noise.

The present disclosure is further described below with reference to some embodiments. The circuit structure employs a phase shifter/attenuator with the phase shift attenuation network shown in FIG. 5 operating at a frequency of 5 GHz to 15 GHz, 7 bits of phase shifting, and 7 bits of attenuation. Selection of the attenuator unit is implemented by a differential switch. A high level (marked as 1) is active, indicating the connection through the attenuator unit, while a low level (marked as 0) indicates a straight-through connection.

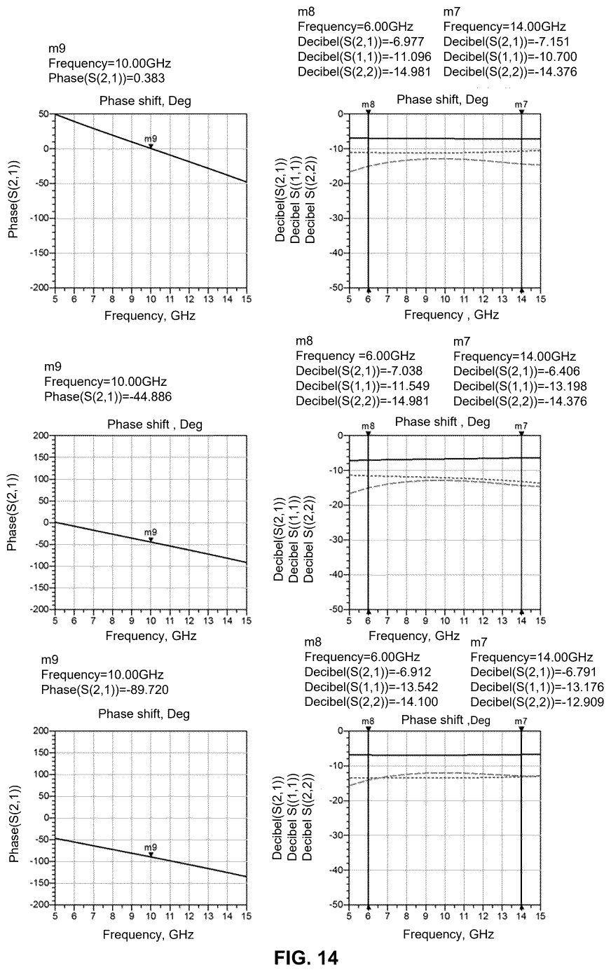

As the schematic diagram illustrating an amplitude-phase relationship shown in FIG. 12, in the absence of attenuation (i.e., an initial amplitude state, marked as ATT0), the amplitude and the phase are controlled by the 7-bit step attenuation (BIT7), and the 8th bit (BIT8) is in a low level state. In the initial amplitude (ATT0) state, the entire phase shifter/attenuator has an insertion loss of −7 dB and enables phase selection from 0 deg to 360 deg. Taking typical phase values of 0 deg, 45 deg, and 90 deg in a first quadrant, the corresponding I-channel and Q-channel attenuation characteristics are 0 deg (I-channel: 31.75 dB, Q-channel: 0 dB), 45 deg (I-channel: 3 dB, Q-channel: 3 dB), and 90 deg (I-channel: 0 dB, Q-channel: 31.75 dB). Simulation results of the phase and S-parameters in the three states are shown in FIG. 14, and in this case, the corresponding truth table for logic control is shown in the following Table 1:

TABLE 1
Logic control truth table for phase shift implementation via 7-bit step attenuation

| | ATT0_0 deg | | ATT0_45 deg | | ATT0_90 deg | |
|---|---|---|---|---|---|---|
| | I--channel | Q-channel | I-channel | Q-channel | I-channel | Q-channel |
| BIT1(0.25 dB) | 1 | 0 | 0 | 0 | 0 | 1 |
| BIT2(0.5 dB) | 1 | 0 | 0 | 0 | 0 | 1 |
| BIT3(1 dB) | 1 | 0 | 1 | 1 | 0 | 1 |
| BIT4(2 dB) | 1 | 0 | 1 | 1 | 0 | 1 |
| BIT5(4 dB) | 1 | 0 | 0 | 0 | 0 | 1 |
| BIT6(8 dB) | 1 | 0 | 0 | 0 | 0 | 1 |
| BIT7(16 dB) | 1 | 0 | 0 | 0 | 0 | 1 |
| BIT8(32 dB) | 0 | 0 | 0 | 0 | 0 | 0 |

It should be noted that the above embodiment shows the three phases of the first quadrant, and can be switched in any of the other three quadrants the quadrant selection circuit as described. The S-parameter is a scattering parameter used to characterize a transmission and reflection relationship of a signal between network ports.

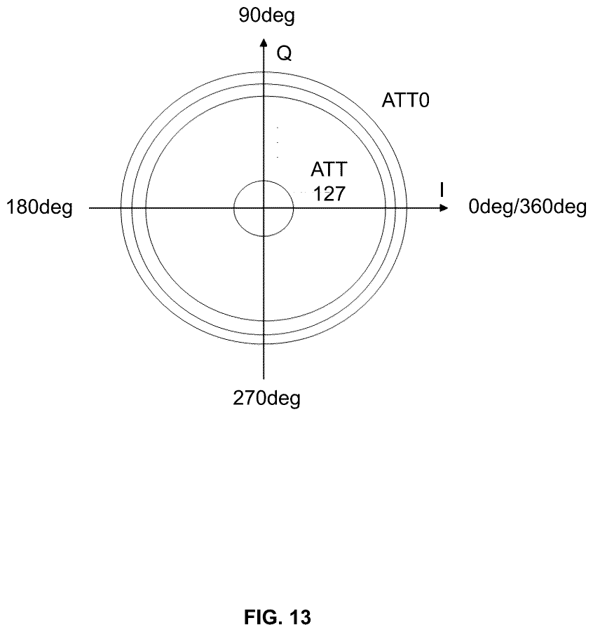

FIG. 13 is a schematic diagram illustrating exemplary S-parameters at different phases under the same amplitude according to some embodiments of the present disclosure.

As shown in the schematic diagram of different attenuation amplitudes in FIG. 13, a function of amplitude selection from 0 dB (i.e., the initial amplitude ATT0) to −32 dB (i.e., a maximum attenuation ATT127) may be realized by the 8th bit step attenuation, 0 dB corresponding to the initial amplitude state ATT0. As shown in FIG. 14, the insertion loss is ATT0=−7 dB. The 7-bit digital attenuator has a total of 128 amplitude states, where a straight-through state or an initial amplitude is denoted as ATT0, a maximum attenuation state is denoted as ATT127, and an intermediate attenuation state is denoted as ATT63, specifically ATT0=−7 dB (corresponding to 0 dB), ATT63=−23 dB (corresponding to −16 dB), and ATT127=−39 dB (corresponding to −32 dB).

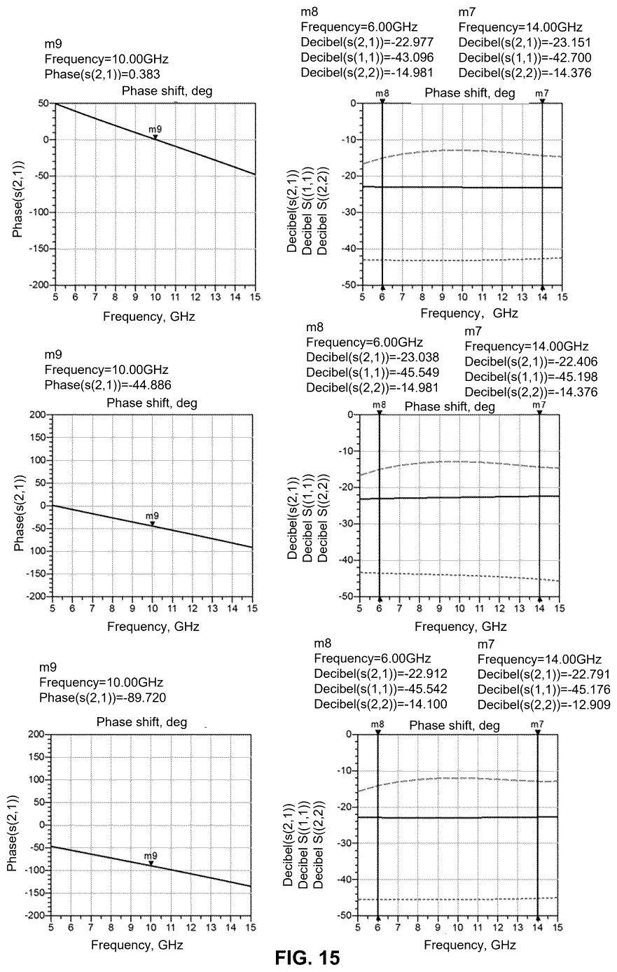

As shown in FIG. 15, FIG. 15 is a schematic diagram illustrating S-parameters at different phases and phase performance under one attenuation amplitude according to some embodiments of the present disclosure, including phase, and S-parameter simulation results of the ATT63 at three phases. Horizontal coordinates of three graphs on the left in FIG. 15 represent frequency and vertical coordinates of the three graphs on the left represent phase. Horizontal coordinates of three graphs on the right in FIG. 15 represent frequency and vertical coordinates of the three graphs on the right represent decibels. In this case, the corresponding logic control truth table is shown in Table 2 below. It can be seen that the amplitude changes from 0 to −16 dB without any change in phase compared to the results shown in FIG. 14.

TABLE 2
Logic control truth table for attenuation implementation via 8-bit step attenuation

| | ATT63_0 deg | | ATT63_45 deg | | ATT63_90 deg | |
|---|---|---|---|---|---|---|
| | I--channel | Q-channel | I-channel | Q-channel | I-channel | Q-channel |
| BIT1(0.25 dB) | 1 | 0 | 0 | 0 | 0 | 1 |
| BIT2(0.5 dB) | 1 | 0 | 0 | 0 | 0 | 1 |
| BIT3(1 dB) | 1 | 0 | 1 | 1 | 0 | 1 |
| BIT4(2 dB) | 1 | 0 | 1 | 1 | 0 | 1 |
| BIT5(4 dB) | 1 | 0 | 0 | 0 | 0 | 1 |
| BIT6(8 dB) | 1 | 0 | 0 | 0 | 0 | 1 |
| BIT7(16 dB) | 0 | 1 | 1 | 1 | 1 | 0 |
| BIT8(32 dB) | 1 | 0 | 0 | 0 | 0 | 1 |

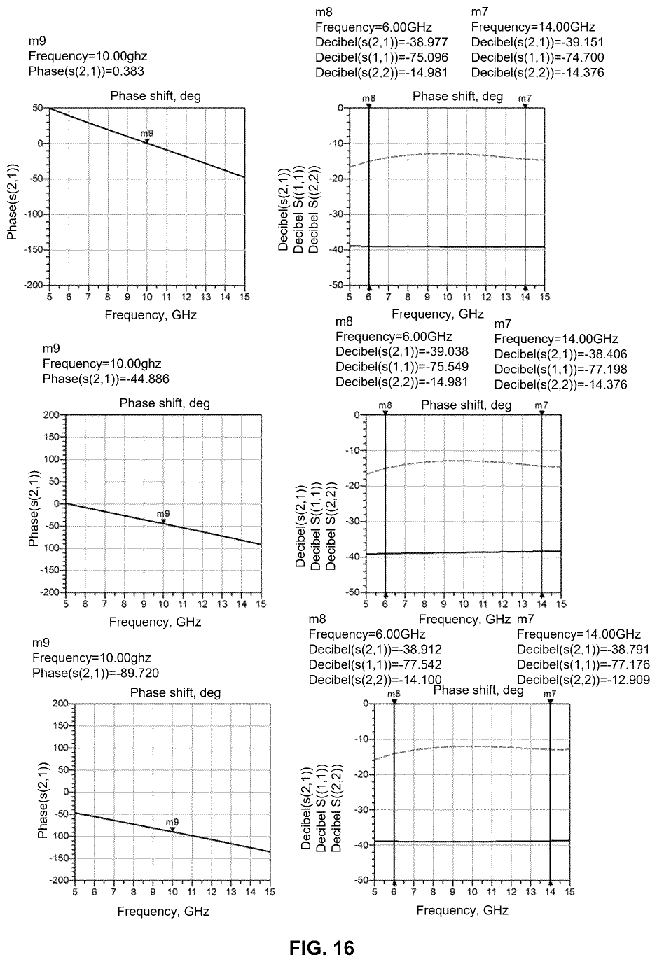

As FIG. 16, FIG. 16 is a schematic diagram illustrating S-parameters at different phases and phase performance under another attenuation amplitude according to some embodiments of the present disclosure, including phase, and e S-parameter simulation results of the ATT127 at three phases. Horizontal coordinates of three graphs on the left in FIG. 16 represent frequency and vertical coordinates of the three graphs on the left represent phase. Horizontal coordinates of three graphs on the right in FIG. 16 represent frequency and vertical coordinates of the three graphs on the right represent decibels. In this case, the corresponding logic control truth table is shown in FIG. 3 below. It can be seen that the amplitude changes from 0 to −32 dB without any change in phase compared to the results shown in FIG. 14.

TABLE 3
Logic control truth table for attenuation implementation via 8-bit step attenuation

| | ATT127_0 deg | | ATT127_45 deg | | ATT127_90 deg | |
|---|---|---|---|---|---|---|
| | I--channel | Q-channel | I-channel | Q-channel | I-channel | Q-channel |
| BIT1(0.25 dB) | 1 | 0 | 0 | 0 | 0 | 1 |
| BIT2(0.5 dB) | 1 | 0 | 0 | 0 | 0 | 1 |
| BIT3(1 dB) | 1 | 0 | 1 | 1 | 0 | 1 |
| BIT4(2 dB) | 1 | 0 | 1 | 1 | 0 | 1 |
| BIT5(4 dB) | 1 | 0 | 0 | 0 | 0 | 1 |
| BIT6(8 dB) | 1 | 0 | 0 | 0 | 0 | 1 |
| BIT7(16 dB) | 1 | 0 | 0 | 0 | 0 | 1 |
| BIT8(32 dB) | 1 | 1 | 1 | 1 | 1 | 1 |

In some embodiments of the present disclosure, the phase shift attenuation network has concise logic control, and achieves the effect of phase shifting and amplitude attenuation through multi-bit step attenuation control. The phase shifter/attenuator constructed based on the phase shift attenuation network has a smaller size and better cost advantage relative to a generic design architecture, and also has smaller insertion loss and higher performance, which means that the insertion loss performance of a single phase shifter and the phase shifter+attenuator is essentially is the same, and the insertion loss does not multiply due to the addition of the attenuation circuit. Furthermore, phase shifting does not introduce additional attenuation, and attenuation does not introduce additional phase.

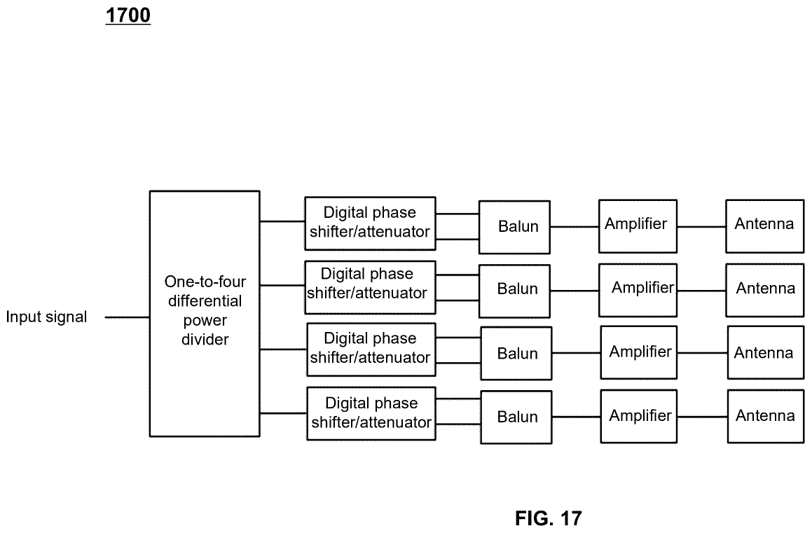

In some embodiments, the present disclosure provides a radio frequency (RF)/microwave transmitting system. The RF/microwave transmitting system may include the phase shift attenuation circuit or the phase shift attenuation network as described above, such as a digital phase shifter/attenuator constructed based on the phase shift attenuation circuit or the phase shift attenuation network as described. FIG. 17 is a schematic structural diagram illustrating an exemplary RF/microwave transmitting system according to some embodiments of the present disclosure. An RF/microwave transmitting system 1700 may include a one-to-four differential power divider configured to convert an input signal used as a differential signal into four differential signals with equal amplitude and identical phases. Input terminals of four digital phase shifters/attenuators may be connected with four output differential ports of the one-to-four differential power divider, respectively. The four digital phase shifters/attenuators may be configured to perform attenuation and phase shifting on the four differential signals output from the one-to-four differential power divider to achieve amplitude attenuation and/or phase shifting. Differential ports of four baluns may be connected with output terminals of the four digital phase shifters, respectively. The four baluns may be configured to convert the four differential signals output from the digital phase shifters/attenuators into four single-ended signals. Input terminals of four amplifiers may be connected with matching ports of the four baluns, respectively. The four amplifiers may be configured to amplify the four single-ended signals output from the baluns. Receiving terminals of four antennas may be connected with output terminals of the four amplifiers. The four antennas may be configured to transmit the four single-ended signals output from the amplifiers. The four-channel RF/microwave transmitter system can be used in systems such as a multibeam power division network, 5G MIMO communications, LEO satellite communications, etc. FIG. 17 is given only as an example, and a count of the digital phase shifters/attenuators, the baluns, the amplifiers, and the antennas included in the RF/microwave transmitting system may be the same as a count of differential output ports of the differential power divider, respectively. For example, if a one-to-two differential power divider is applied, the count of the digital phase shifters/attenuators, the baluns, the amplifiers, and the antennas may be two; if a one-to-eight differential power divider is applied, the count of the digital phase shifters/attenuators, the baluns, the amplifiers, and the antennas may be eight. If no differential operation is performed, the count of the digital phase shifters/attenuators, the baluns, the amplifiers, and the antennas may be one.

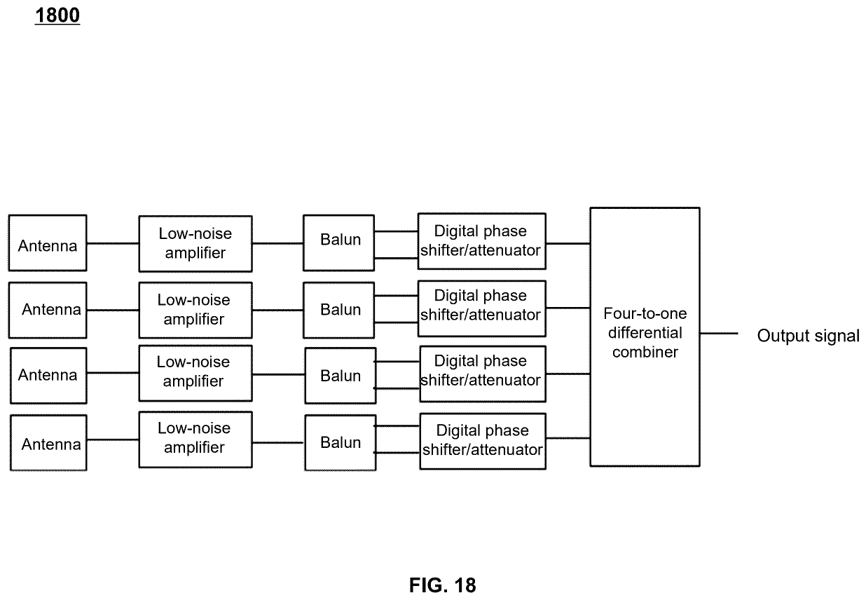

In some embodiments, an RF/microwave receiving system may include the phase shift circuit as described above, such as a digital phase shifter/attenuator constructed based on the phase shift attenuation circuit or the phase shift attenuation network as described. Referring to FIG. 18, FIG. 18 is a schematic structural diagram illustrating an exemplary RF/microwave receiving system according to some embodiments of the present disclosure. An RF/microwave receiving system 1800 may include four antennas configured to receive four single-ended signals. Input terminals of four low-noise amplifiers may be connected with four antennas, respectively. The four low-noise amplifiers may be configured to amplify the four single-ended signals received by the antennas. Matching ports of four baluns may be connected with output terminals of the four low-noise amplifiers, respectively. The four baluns may be configured to convert the four single-ended signals output from the low-noise amplifiers into four differential signals. Input terminals of the four digital phase shifters/attenuators may be connected with differential ports of the four baluns, respectively. The four digital phase shifters/attenuators may be configured to perform phase shifting and attenuation on the four differential signals output from the baluns to achieve amplitude attenuation and/or phase shifting. Four output differential ports of a one-to-four differential power divider may be connected with output terminals of four digital attenuators, respectively. The one-part-four differential power divider may be configured to convert four differential signals output from the digital phase shifters/attenuators into one differential signal. The four-channel RF/microwave receiving system can be used in systems such as a multibeam power division network, 5G MIMO communications, LEO satellite communications, etc. Similarly, FIG. 18 is given only as an example, and a count of the digital phase shifters, the digital attenuators, the baluns, the amplifiers, and the antennas included in the RF/microwave receiving system may be the same as a count of differential output ports of the differential power divider, respectively. For example, if a one-to-two differential power divider is applied, the count of the digital phase shifters, the digital attenuators, the baluns, the amplifiers, and the antennas may be two; if a one-to-eight differential power divider is applied, the count of the digital phase shifters, the digital attenuators, the baluns, the amplifiers, and the antennas may be eight. If no differential combination is performed, the count of the digital phase shifters, the digital attenuators, the baluns, the amplifiers, and the antennas may be one.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures, or features may be combined as suitable in one or more embodiments of the present disclosure.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

What is claimed is:

1. A phase shift attenuation circuit, comprising:
a plurality of first differential circuits electrically connected in sequence; an electrical connection between two adjacent first differential circuits of the plurality of first differential circuits including at least one of a straight-through connection or a connection through an attenuator unit; wherein
the phase shift attenuation circuit realizes 8-bit step attenuation through the attenuator unit; 7-bit step attenuation among the 8-bit step attenuation is configured to realize a phase shift function, and the 8-bit step attenuation is configured to realize phase shift and attenuation functions.

2. The phase shift attenuation circuit of claim 1, wherein each of the plurality of first differential circuits includes:
one or more first differential input ports, one or more first differential output ports, and a plurality of switching tube chips; wherein
one of the plurality of switching tube chips is connected between a positive and negative interface of each of the one or more first differential input ports and a positive and negative interface of each of the one or more first differential output ports;
connection or disconnection between the one or more first differential input ports and the one or more first differential output ports is achieved by the plurality of switching tube chips to determine the electrical connection between the two adjacent first differential circuits.

3. The phase shift attenuation circuit of claim 2, wherein the plurality of first differential circuits are different.

4. The phase shift attenuation circuit of claim 1, wherein an attenuation range of the 7-bit step attenuation is in a range of 0-31.75 dB for realizing phase shifting in a range of 0 deg-90 deg; an attenuation range of the 8-bit step attenuation is in a range of 0-63.75 dB for realizing phase shifting in a range of 0 deg-90 deg and amplitude attenuation.

5. A phase shift attenuation network, comprising the phase shift attenuation circuit of claim 1.

6. The phase shift attenuation network of claim 5, further comprising:
a first node circuit;
a second node circuit; and
a first signal channel and a second signal channel which are coupled between the first node circuit and the second node circuit; wherein
the first node circuit and the second node circuit include the phase shift attenuation circuit, respectively.

7. The phase shift attenuation network of claim 6, wherein the first node circuit and the second node circuit respectively include a quadrant conversion circuit electrically connected with the phase shift attenuation circuit; wherein
the quadrant conversion circuit is constructed based on a second differential circuit; the second differential circuit realizes quadrant conversion of a phase through connection or disconnection between a positive and negative interface of a second differential input port and a positive and negative interface of a second differential output port, and realizes phase shifting in a preset range based on the phase shift attenuation circuit.

8. The phase shift attenuation network of claim 7, wherein a phase shift range of the first node circuit or the second node circuit is in a range of 0 deg-360 deg.

9. The phase shift attenuation network of claim 6, wherein the second node circuit includes a third differential circuit, the third differential circuit includes:
an input differential network including a first port and a second port;
an input differential unit including an input differential coupling line;
an output differential unit including a first coupling line and a second coupling line; and
an output differential network including a first output differential port and a second output differential port; wherein
a positive input terminal of the input differential coupling line is connected with the first port, and a negative input terminal of the input differential coupling line is connected with the second port;
a positive input terminal of the first coupling line is connected with a positive output terminal of the input differential coupling line, and a negative input terminal of the second coupling line is connected with a negative output terminal of the input differential coupling line;
a negative input terminal of the first coupling line is connected with a positive input terminal of the second coupling line;
a positive interface of the first output differential port is connected with a positive output terminal of the first coupling line, and a negative interface of the first output differential port is connected with a negative output terminal of the second coupling line;
a positive interface of the second output differential port is connected with a positive output terminal of the second coupling line, and a negative interface of the second output differential port is connected with a negative output terminal of the first coupling line;
the first output differential port and the second output differential port of the output differential network are configured to receive a first phase shift signal and a second phase shift signal, respectively, and the input differential network is configured to output a synthesized signal.

10. A radio frequency (RF) microwave system, comprising the phase shift attenuation circuit of claim 1.

11. A radio frequency (RF) microwave system, comprising the phase shift attenuation network of claim 5.
